(19) United States
(12) Patent Application Publication
(10) Pub. No.: US 2022/0258147 A1
(43) Pub. Date: Aug. 18, 2022

(54) PHOTOCATALYSIS USING MIE RESONANCES OF Cu2O DIELECTRIC NANOSTRUCTURES

(71) Applicant: The Board of Regents for the Oklahoma Agricultural and Mechanical Colleges, Stillwater, OK (US)

(72) Inventors: Marimuthu Andiappan, Stillwater, OK (US); Aaron Jacob Wheeler, Tulsa, OK (US); Addanki Tirumala Ravi Teja, Stillwater, OK (US); Farshid Mohammadparast, Stillwater, OK (US); Sundaram Bhardwaj Ramakrishnan, Stillwater, OK (US)

(21) Appl. No.: 17/735,850

(22) Filed: May 3, 2022

Related U.S. Application Data
(63) Continuation of application No. PCT/US20/59445, filed on Nov. 6, 2020.
(60) Provisional application No. 62/932,991, filed on Nov. 8, 2019.
(60) Provisional application No. 63/013,215, filed on Apr. 21, 2020.

(51) Int. Cl. B01J 35/02; B01J 35/00; B01J 35/08; H01L 31/0224

(52) U.S. Cl. CPC B01J 35/026; B01J 35/004; B01J 23/72; B01J 35/08; H01L 31/022425; B01J 35/023

(57) ABSTRACT

Improved photocatalytic and photovoltaic materials wherein an additional energy transfer pathway is available between an optical illumination source and a targeted adsorbate molecule. Dielectric particles are sized and shaped to produce electron excitations and subsequent user-defined chemical transformation without exceeding a band gap energy barrier of the dielectric. Thus, energy transfers that occur between the novel dielectric material and the target adsorbate happen via Mie resonance mediated energy and electron transfer (MRET), which possesses the unique trait of having the capacity to occur below the conduction band.

### CROSS REFERENCE TO RELATED APPLICATIONS/INCORPORATION BY REFERENCE STATEMENT

This application is a non-provisional application claiming benefit to the international application no. PCT/US20/59445 filed on Nov. 6, 2020, which claims priority to provisional application U.S. Ser. No. 62/932,991 filed Nov. 8, 2019, and provisional application U.S. Ser. No. 63/013,215 filed Apr. 21, 2020. The entire contents of each of the above-referenced applications are expressly incorporated herein by reference.

### BACKGROUND

Photovoltaics and solar thermal collectors are most widely used for solar energy generation. Until now, this field has been dominated by photovoltaic devices, usually made of silicon, and profiting from the experience in manufacturing and material availability resulting from the semiconductor industry. Understanding the working mechanisms, one can recognize that two common limitations exist in solar utilization schemes—the limited light absorption and the rapid charge recombination in semiconductors. Some semiconductors have been explored for photocatalytic and photovoltaic applications, but they possess relatively low light absorption coefficients. Semiconductors and hybrid semiconductors with wide bandgaps such as TiO₂ (Eg=3.2 eV) can only absorb light limited to the ultraviolet region and cannot utilize the visible and near-infrared photons that account for a significant portion of the solar spectrum.

The field of plasmonics has contributed significantly to photovoltaics (PV) and photocatalysis, where design approaches based on localized surface plasmon resonance (LSPR) can be used to improve photon-electron coupling in photovoltaic devices, reducing the thickness of solar photovoltaic absorber layers, and leading to novel solar-cell design. Light trapping using gold nanoparticles annealed to the electrode can increase the power conversion efficiency of the solar cell up to 10%. Films of 100 nm Ag particles have been fabricated by depositing size-selected aerosols on substrates using electrophoresis and these films enhance the short-circuit current density on silicon PV cells due to improved light trapping. Various combinations of plasmonic materials like noble metals Au and Ag with semiconductors like TiO₂, SiO₂, Cu₂O have been explored as photo electrodes to improve the absorption and reduce electron-hole recombination thus converting solar energy to fuel energy with advantages like tuning selectivity. These nanocrystalline and conducting polymers films using plasmonic metals like Ag and Au have promising applications in third generation solar cells like dye-sensitized solar cells, quantum dot-based solar cells, and perovskite solar cells, but the noble metals are scarce, expensive, and possess limitations like momentum mismatch for surface plasmon polaritons (SPPs), fabrication complexities, and parasitic absorption.

Most plasmonic metal nanocatalysts (PMN) are plagued by inherent joule loss, band-gap limitations, and the inability to showcase strong magnetic fields. In addition, several of the metal catalysts currently being used in industrial and pharmaceutical applications are toxic in nature and require expensive downstream operations. There is a need in the art for new and improved photocatalytic and photovoltaic materials that overcome the disadvantages and defects of the prior art. It is to such compositions, as well as methods of production and use thereof, that the present disclosure is directed.

### BRIEF DESCRIPTION OF THE DRAWINGS

FIG. 1A illustrates how semiconductor materials can be used in photocatalysis through band gap mediated excitation where excited electrons in the conduction band can populate the adsorbates.

FIG. 1B illustrates how plasmonic nanostructures can populate the adsorbates through localized surface plasmon resonance (LSPR).

FIG. 1C illustrates dielectric nanostructures which can exhibit Mie resonances, where electron excitations below the band gap can be used for photocatalysis.

FIG. 2 is a perspective view of a Luzchem EXP-01™ photoreactor (Luzchem Research, Ontario Canada) with LZC-UV™ and LZC-LBL™ bulbs along with suspended quartz chamber.

FIG. 3A shows the differences between Cu₂O spherical nanoparticles (NP) and nanocubes (NC), including UV Spectra and TEM images.

FIG. 3B shows the change in NC ultraviolet to visible (UV-VIS) spectra across synthetization time.

FIG. 4 shows the visible light absorption spectra for various tested organic dyes, Luzchem tube settings, and Cu₂O novel material sizes and geometries.

FIG. 5A shows absorption spectra of methylene blue (MB) dye in presence of Cu₂O NCs upon irradiation of LZC-LBL (Luzchem Research blue) and LZC-LGR (Luzchem Research green) bulbs.

FIG. 5B shows possible mechanisms of the MB dye degradation using green and blue light with 520±10 nm and 455±5 nm are Band gap mediated charge transfer.

FIG. 5C illustrates the absorbance region and theoretical bandgap of the Cu₂O NCs, as well as the absorbance region of the initial MB sample and LZC-LBL and LZC-LGR bulbs.

FIG. 6A shows absorption spectra of MB in presence of Cu₂O NCs upon irradiation of the LZC-LRD bulbs.

FIG. 6B shows possible mechanisms of this degradation.

FIG. 6C illustrates an absorbance region including theoretical bandgap of the Cu₂O NCs, as well as the absorbance region of the initial MB sample and LZC-LRD bulbs.

FIG. 7A shows absorption spectra of methyl orange MO dye in presence of Cu₂O NCs upon irradiation of the LZC-LRD bulbs.

FIG. 7B shows possible mechanisms of this MO dye degradation.

FIG. 7C illustrates absorbance regions including theoretical bandgap of the Cu₂O NCs, as well as the absorbance region of the initial MO sample and LZC-LRD bulbs.

FIG. 8 is a comparison of successful degradations using NCs as well as control experiments performed over various periods of times, formatted in the form of Dye/Catalyst type/Bulb utilized.

FIG. 9A shows absorption spectra of MB in presence of Cu₂O NPs upon irradiation of the LZC-LRD bulbs.

FIG. 9B shows possible mechanisms of this MB degradation.

FIG. 9C illustrates the absorbance region including theoretical bandgap of the Cu₂O NPs, as well as the absorbance region of the initial methylene blue (MB) dye sample and LZC-LRD bulbs.

FIG. 10A shows dye sensitization and electron transfer into Cu₂O small nanospheres.

FIG. 10B shows LSPR-enhanced dye sensitization and electron transfer into SC.

FIG. 10C shows Mie resonance enhanced dye sensitization and electron transfer into Cu₂O large nanocubes.

FIG. 10D shows dye sensitization via Mie resonance.

FIG. 11A is an absorbance spectrum of Methylene Blue and Red-light Source spectrum showing good overlap. X-axis values: 400-900 nm.

FIG. 11B is a schematic diagram of MB dye sensitization followed by degradation via superoxide (O2− radical) as intermediate species.

FIG. 11C is a comparison of methylene blue (MB) degradations using Cu₂O NCs (Cubes) and Cu₂O NPs (Small Spheres) dispersed in dimethyl formamide (DMF) under illumination of red light.

FIG. 12A shows absorption spectra of Cu₂O NCs (Cubes) and Cu₂O NPs (Small Spheres) synthesized using De-wetting technique and micro-emulsion method.

FIG. 12B shows the absorption efficiency of Cu₂O NCs and Cu₂O NPs for the average transmission electron microscopy (TEM) particle size shown in FIGS. 12C and D. TEM images of Cu₂O NCs (Cubes) and Cu₂O NPs (Small Spheres) of size 327±125 nm and 47±6 nm respectively.

FIG. 12C is a TEM image of Cu₂O NCs (Cubes) of size 327±125 nm.

FIG. 12D is a TEM image of Cu₂O NPs (Small Spheres) of size 47±6 nm.

FIG. 13A depicts methylene blue in dimethylformamide (DMF) and absence of catalyst showing slight degradation in comparison to presence of Cu₂O nanocubes. Adding Benzoquinone which is a O₂− radical scavenger to the reaction mixture in presence of Cu₂O nanocubes to the nitrogen bubbled DMF (to minimize the dissolved oxygen) in inert atmosphere is similar to absence of catalyst under same conditions.

FIG. 13B depicts the extinction efficiency of Cu₂O cubes (25 nm, 50 nm, 100 nm, 200 nm, 300 and 400 nm).

FIG. 13C depicts the extinction efficiency of TiO₂ cubes (25 nm, 50 nm, 100 nm, 200 nm, 300 and 400 nm).

FIG. 13D depicts the extinction efficiency of Fe₂O₃ cubes of size 50, 100, 200, 300, and 400 nm.

FIG. 14 is a schematic illustration of a photocatalytic flow reactor wherein light illumination is from inside.

FIG. 15 is a schematic illustration of a photocatalytic flow reactor wherein light illumination is from outside of the flow reactor.

### DETAILED DESCRIPTION

Before explaining at least one embodiment of the inventive concept(s) in detail by way of exemplary language and results, it is to be understood that the inventive concept(s) is not limited in its application to the details of construction and the arrangement of the components set forth in the following description. The inventive concept(s) is capable of other embodiments or of being practiced or carried out in various ways. As such, the language used herein is intended to be given the broadest possible scope and meaning; and the embodiments are meant to be exemplary—not exhaustive. Also, it is to be understood that the phraseology and terminology employed herein is for the purpose of description and should not be regarded as limiting.

Unless otherwise defined herein, scientific and technical terms used in connection with the presently disclosed inventive concept(s) shall have the meanings that are commonly understood by those of ordinary skill in the art. Further, unless otherwise required by context, singular terms shall include pluralities and plural terms shall include the singular. The foregoing techniques and procedures are generally performed according to conventional methods well known in the art and as described in various general and more specific references that are cited and discussed throughout the present specification. The nomenclatures utilized in connection with, and the laboratory procedures and techniques of, analytical chemistry, synthetic organic chemistry, and medicinal and pharmaceutical chemistry described herein are those well-known and commonly used in the art. Standard techniques are used for chemical syntheses and chemical analyses.

All patents, published patent applications, and non-patent publications mentioned in the specification are indicative of the level of skill of those skilled in the art to which this presently disclosed inventive concept(s) pertains. All patents, published patent applications, and non-patent publications referenced in any portion of this application are herein expressly incorporated by reference in their entirety to the same extent as if each individual patent or publication was specifically and individually indicated to be incorporated by reference.

All of the compositions and/or methods disclosed herein can be made and executed without undue experimentation in light of the present disclosure. While the compositions and methods of the inventive concept(s) have been described in terms of particular embodiments, it will be apparent to those of skill in the art that variations may be applied to the compositions and/or methods and in the steps or in the sequence of steps of the methods described herein without departing from the concept, spirit, and scope of the inventive concept(s). All such similar substitutions and modifications apparent to those skilled in the art are deemed to be within the spirit, scope, and concepts of the inventive concept(s) as defined by the appended claims.

As utilized in accordance with the present disclosure, the following terms, unless otherwise indicated, shall be understood to have the following meanings:

The use of the term “a” or “an” when used in conjunction with the term “comprising” in the claims and/or the specification may mean “one,” but it is also consistent with the meaning of “one or more,” “at least one,” and “one or more than one.” As such, the terms “a,” “an,” and “the” include plural referents unless the context clearly indicates otherwise. Thus, for example, reference to “a compound” may refer to one or more compounds, two or more compounds, three or more compounds, four or more compounds, or greater numbers of compounds. The term “plurality” refers to “two or more.”

The use of the term “at least one” will be understood to include one as well as any quantity more than one, including but not limited to, 2, 3, 4, 5, 10, 15, 20, 30, 40, 50, 100, etc. The term “at least one” may extend up to 100 or 1000 or more, depending on the term to which it is attached; in addition, the quantities of 100/1000 are not to be considered limiting, as higher limits may also produce satisfactory results. In addition, the use of the term “at least one of X, Y, and Z” will be understood to include X alone, Y alone, and Z alone, as well as any combination of X, Y, and Z. The use of ordinal number terminology (i.e., “first,” “second,” “third,” “fourth,” etc.) is solely for the purpose of differentiating between two or more items and is not meant to imply any sequence or order or importance to one item over another or any order of addition, for example.

The use of the term “or” in the claims is used to mean an inclusive “and/or” unless explicitly indicated to refer to alternatives only or unless the alternatives are mutually exclusive. For example, a condition “A or B” is satisfied by any of the following: A is true (or present) and B is false (or not present), A is false (or not present) and B is true (or present), and both A and B are true (or present).

As used herein, any reference to “one embodiment,” “an embodiment,” “some embodiments,” “one example,” “for example,” or “an example” means that a particular element, feature, structure, or characteristic described in connection with the embodiment is included in at least one embodiment. The appearance of the phrase “in some embodiments” or “one example” in various places in the specification is not necessarily all referring to the same embodiment, for example. Further, all references to one or more embodiments or examples are to be construed as non-limiting to the claims.

Throughout this application, the term “about” is used to indicate that a value includes the inherent variation of error for a composition/apparatus/device, the method being employed to determine the value, or the variation that exists among the study subjects. For example, but not by way of limitation, when the term “about” is utilized, the designated value may vary by plus or minus twenty percent, or fifteen percent, or twelve percent, or eleven percent, or ten percent, or nine percent, or eight percent, or seven percent, or six percent, or five percent, or four percent, or three percent, or two percent, or one percent from the specified value, as such variations are appropriate to perform the disclosed methods and as understood by persons having ordinary skill in the art.

As used in this specification and claim(s), the words “comprising” (and any form of comprising, such as “comprise” and “comprises”), “having” (and any form of having, such as “have” and “has”), “including” (and any form of including, such as “includes” and “include”), or “containing” (and any form of containing, such as “contains” and “contain”) are inclusive or open-ended and do not exclude additional, unrecited elements or method steps.

The term “or combinations thereof” as used herein refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB. Continuing with this example, expressly included are combinations that contain repeats of one or more item or term, such as BB, AAA, AAB, BBC, AAABCCCC, CBBAAA, CABABB, and so forth. The skilled artisan will understand that typically there is no limit on the number of items or terms in any combination, unless otherwise apparent from the context.

Also, any range listed or described herein is intended to include, implicitly or explicitly, any number within the range, particularly all integers, including the end points, and is to be considered as having been so stated. For example, “a range from 1 to 10” is to be read as indicating each possible number, particularly integers, along the continuum between about 1 and about 10, including for example 2, 3, 4, 5, 6, 7, 8, and 9. Similarly, fractional amounts between any two consecutive integers are intended to be included herein, such as, but not limited to, 0.05, 0.1, 0.15, 0.2, 0.25, 0.3, 0.35, 0.4, 0.45, 0.5, 0.55, 0.6, 0.65, 0.7, 0.75, 0.8, 0.85, 0.9, and 0.95. For example, the range 3 to 4 includes, but is not limited to, 3.05, 3.1, 3.15, 3.2, 3.25, 3.3, 3.35, 3.4, 3.45, 3.5, 3.55, 3.6, 3.65, 3.7, 3.75, 3.8, 3.85, 3.9, and 3.95. Thus, even if specific data points within the range, or even no data points within the range, are explicitly identified or specifically referred to, it is to be understood that any data points within the range are to be considered to have been specified, and that the inventors possessed knowledge of the entire range and the points within the range.

As used herein, the term “substantially” means that the subsequently described event or circumstance completely occurs or that the subsequently described event or circumstance occurs to a great extent or degree. For example, when associated with a particular event or circumstance, the term “substantially” means that the subsequently described event or circumstance occurs at least 80% of the time, or at least 85% of the time, or at least 90% of the time, or at least 95% of the time. For example, the term “substantially adjacent” may mean that two items are 100% adjacent to one another, or that the two items are within close proximity to one another but not 100% adjacent to one another, or that a portion of one of the two items is not 100% adjacent to the other item but is within close proximity to the other item.

Plasmonic metal materials have typically been employed in the past to mediate energy transfer between optically illuminated excited electrons known as plasmons, and reactant materials commonly referred to as adsorbates. This phenomenon is referred to as plasmonic catalysis, the encompassment of a variety of different mechanisms including direct and indirect electron transfer. However, these plasmonic metals are plagued by inherent joule loss, band-gap limitations and the inability to showcase strong magnetic fields. In addition, several of the plasmonic metal photocatalysts being currently used in industrial applications are expensive and toxic. Heavy metals such as palladium and platinum are examples of some of these harmful materials. Hence, prior art processes for the utilization of these plasmonic metals can be described as cumbersome, time-consuming, and capital-intensive.

Most common heterogeneous photocatalysts are transition metal oxides and semiconductors, which have unique characteristics. Unlike the metals which have a continuum of electronic states, semiconductors possess a void energy region where no energy levels are available to promote recombination of an electron and hole produced by photoactivation in the solid. The void region, which extends from the top of the filled valence band to the bottom of the vacant conduction band, is called the band gap. When a photon with energy equal to or greater than the semiconductor's band gap is absorbed by the semiconductor, an electron is excited from the valence band to the conduction band, generating a positive hole in the valence band. In the inventive concepts described below, the semiconductor is a dielectric particle with a size and shape to produce these electron excitations from photons that surprisingly can have energy that is less than the band gap. The dielectric particles can then facilitate reactions between the excited electrons with oxidants to produce reduced products, and/or reactions between the generated holes with reductants to produce oxidized products. A large variety of reactions are possible including oxidation, dehydrogenation, hydrogen transfer, metal deposition, water detoxification, gaseous pollutant removal, among others. These oxidation-reduction reactions generally take place at the surface of the semiconductor or dielectric particles, and thus the reactants are often referred to as adsorbents.

Previous reports suggest that researchers believe copper-based catalysts undergo energy transfers via plasmonic mechanisms stemming from localized surface plasmon resonance effects (LSPR) as well as standard semiconductor mechanisms that come into play once the semiconductor material's bandgap energy barrier is exceeded. These effects, when utilized with the proper light intensity and wavelength, are capable of driving an electron from the occupied adsorbate states, to unoccupied adsorbate states, either via direct charge excitation or indirect charge excitation. Once this electron is found in the unoccupied adsorbate state, desired chemical transformations may occur. Cuprous oxide (Cu₂O) is a p-type semiconductor with a band gap of 2.1 eV and is a molecule that has recently been identified as dielectric in nature. Dielectric nanostructures are a relatively new focus in nanoscale optic-based research today, with their uniquely enhanced magnetic and electric field properties being exploited for the development of high performance nanoantennas, electromagnetic cloaking, metamaterials and nanophotonic devices. However, the following examples show that the photocatalyst in the form of the dielectric nanoparticle Cu₂O is capable of providing a pathway for energy transfer between an optical illumination source and a targeted adsorbate molecule, opening a new way to do solar light harvesting and photocatalysis near the bandgap and even below the bandgap of semiconductor materials.

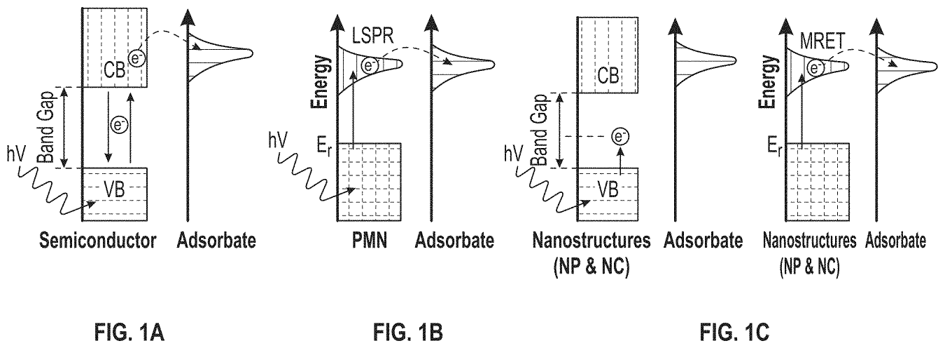

A band gap of 2.1 eV roughly translates to a wavelength of 590 nm, and according to traditional past understanding of semiconductor catalysis, this meant that in order for an electron to separate from the conduction band of the Cu₂O particle and into the anti-bonding valance band, a light wavelength in the ultraviolet (UV) frequency range or a frequency between 380 nm through 590 nm in the visible light region was necessary. However, experiments performed in this study have showcased that charge excitation and subsequent chemical transformation is possible without exceeding the band gap energy barrier. This novel concept is made possible by the Cu₂O particle's unique ability to display Mie resonance characteristics, which promote higher magnetic field magnitudes at certain dipole and quadrupole moments. This study provides and supports the theory that energy transfer can occur between the Cu₂O novel material and the target adsorbate via Mie Resonance mediated Energy and Electron transfer (MRET) and Mie resonance mediated Near Field Effect (MRNFE). Table 1 below and FIGS. 1A-1C showcase the individual mechanism types.

TABLE 1
Energy Transfer Mechanisms

| (a) Semiconductor | | (b) Plasmonic Resonances | | (c) Mie Resonances | |
|---|---|---|---|---|---|
| hv ≥ 590 nm | Electrons | Absorbance | Chemical- | Absorbance | Mie |
| (2.1 eV) | transfer from | | Interface- | | Resonance |
| | conduction band | | Damping | | mediated |
| | into valence | | (CID), | | Energy |
| | band, allowing | | Landau | | Transfer |
| | them to populate | | Damping | | (MRET) |
| | the adsorbate | | (LD) | | |
| | states | | | | |
| hv ≤ 590 nm | The electrons | Scattering | Near Field | Scattering | Mie |
| (2.1 eV) | lacking sufficient | | Effect (NFE) | | resonance |
| | energy to reach | | | | mediated |
| | the valence | | | | Near Field |
| | band, fall back | | | | Effect |
| | into the | | | | (MRNFE) |
| | conduction band | | | | |
| | or virtual states | | | | |

As seen in FIG. 1A, 590 nm of light wavelength frequency is needed for typical semiconductor catalysis to occur. As seen in FIG. 1B, in typical plasmonic catalysis, once there is overlap between the excited plasmons and the unpopulated adsorbate states, electron transfer is possible, either directly or indirectly. Comparatively, in FIG. 1C, the bandgap does not need to be exceeded, nor does there need to be a specific overlap in order for energy transfer to occur in MRET type mechanisms. Furthermore, there are two types of Near Field Effects, plasmonic NFE and MRNFE. The near field effect localizes electrons at the surface/corners of the Cu₂O material and causes the antibonding electrons to be capable of degradation. This phenomenon only occurs whenever there is an overlap projection between the adsorbate or organic dye's peak absorbance and the utilized light wavelength frequency. Whenever there is sufficient light wavelength overlap projection, the adsorbate absorbs the energy from the light and destabilizes, this causes the dye molecule's bonds to become extremely weak or even break apart in some cases.

A novel composition can be made of dielectric particles that are sized and shaped to produce electron excitations and subsequent user-defined chemical transformation without exceeding a band gap energy barrier of the dielectric. These sized and shaped dielectric particles can be used in virtually any photocatalytic process. Nonlimiting examples of suitable chemical transformations include water purification, self-cleaning and depolluting materials, photoelectrochemical conversion, production of targeted pharmaceutically active compounds for drug synthesis, and the like. Within each of these applications, the user can determine if the photocatalyst currently employed (TiO₂ in most cases) can be reconfigured (i.e., by adjusting the size and shape) to optimize its MRET effects. Optimizing the MRET effects can result in increased efficiency and lower utility costs due to less light energy being needed. The user can also redefine the process to employ a completely different material such as, for example, Cu₂O, to meet the product demand while saving on raw material costs, utility costs, and potentially mitigating other unwanted aspects to their current process such as toxicity concerns and the like.

A novel MRET-based dye-sensitized solar cell (DSSC) is also made possible using the dielectric particles described above and in one embodiment, the sized and shaped dielectric particles are used in a DSSC. DSSCs belong to a group of thin-film solar cells which have been under extensive research for more than two decades due to their low cost, simple preparation methodology, low toxicity and ease of production. A DSSC includes a working electrode soaked with a sensitizer or dye and sealed to the counter electrode with a thin layer of electrolyte. Prior art working electrodes are typically prepared by depositing a thin layer of oxide semiconducting materials such as TiO₂, Nb₂O₅, ZnO, SnO₂ (n-type), and NiO (p-type) on a transparent conducting glass plate. However, in the present MRET-based DSSC, the electrodes are made of dielectric particles on a transparent conducting glass plate. Because the semiconducting or dielectric particles absorb only a small fraction of light in the UV region, the working electrodes are immersed in a mixture of a photosensitive molecular sensitizer or dye. After soaking the film within the dye solution, the dye gets covalently bonded to the semi-conducting or dielectric particle surface. Due to the highly porous structure and the large surface area of the electrode particles, a high number of dye molecules get attached, and light absorption at the particle surface increases. The bulk of the semiconductor or dielectric particles are typically only used as a charge transporter and the photoelectrons are provided by photosensitive dyes as the dye is the component responsible for the maximum adsorption of incident light. However, by using a dye adsorbed onto the surface of dielectric particles that are sized and shaped to optimize MRET effects, energy transfer between an optical illumination source and the dye is increased and the efficiency of the DSSC is significantly improved.

The DSSC has four basic steps: light adsorption, electron injection, transportation of carrier, and collection of current. The incident light is absorbed by the dye or photosensitizer. Due to the light absorption, electrons get promoted from the ground state to an excited state in the dye. The excited electrons have a nanosecond-ranged lifetime and are injected into the conduction band of the semiconducting or dielectric particles beneath the adsorbed dye layer. By increasing the range of absorbable wavelengths and “injectable” excited electrons, the overall efficiency of the DSSC is improved. The dielectric particles can also absorb a small fraction of the solar photons. The injected electrons are transported between the dielectric particles back toward the counter electrode which is typically platinum or carbon. The electrolyte comprises a redox couple such as I⁻/I⁻₃, for example. The electrons at the counter electrode reduce I⁻₃ to I⁻ and regeneration of the dye ground state takes place by the dye accepting electrons from I⁻ and oxidation of I⁻ to I⁻₃.

Nonlimiting examples of suitable dielectric particles include Cu₂O, TiO₂, and Fe₂O₃. In one embodiment, the dielectric particles have a weight-average particle diameter in a range of from about 75 nm to about 400 nm. In another embodiment the weight-average particle diameter is in a range of from about 250 nm to about 400 nm. In yet another embodiment, the weight-average particle diameter is in a range of from about 40 nm to about 60 nm.

In one embodiment, the dielectric particles have a generally cubic shape. In another embodiment, the dielectric particles have a generally spherical shape. However, other shapes can be used including, but not limited to, rectangular bars, octahedrons, cubo-octahedrons, and triangular plates.

A novel photocatalytic treatment method is provided that includes the step of irradiating the photocatalytic dielectric particles described above in combination with a reactant, wherein the irradiating light has a lower energy than the band gap energy of the photocatalytic dielectric particles, and the lower energy irradiating light produces electron excitations and subsequent user-defined chemical transformation of the reactant without exceeding the band gap energy barrier of the dielectric particles. In one embodiment, the irradiating light has a wavelength longer than ultraviolet. In another embodiment, the irradiating light is in the visible spectrum. In either case, the irradiating light can include solar light or artificial light.

To support the new Mie mechanism concepts, an experiment designed around the degradation of an adsorbate (organic dye molecules in this case), under various sizes and shapes of the Cu₂O catalyst was designed and performed under various light wavelength conditions as described below.

### EXAMPLE 1

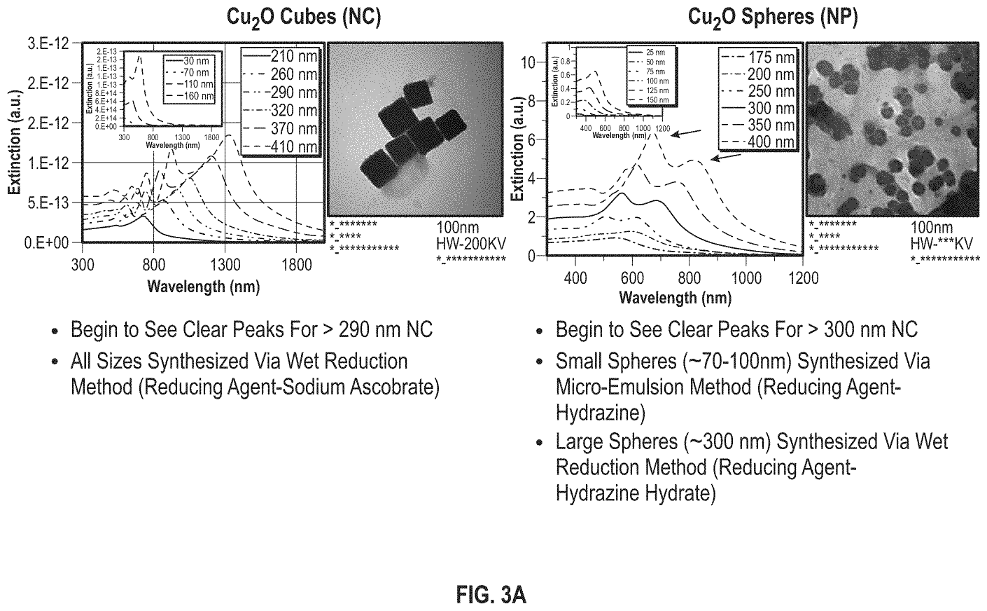

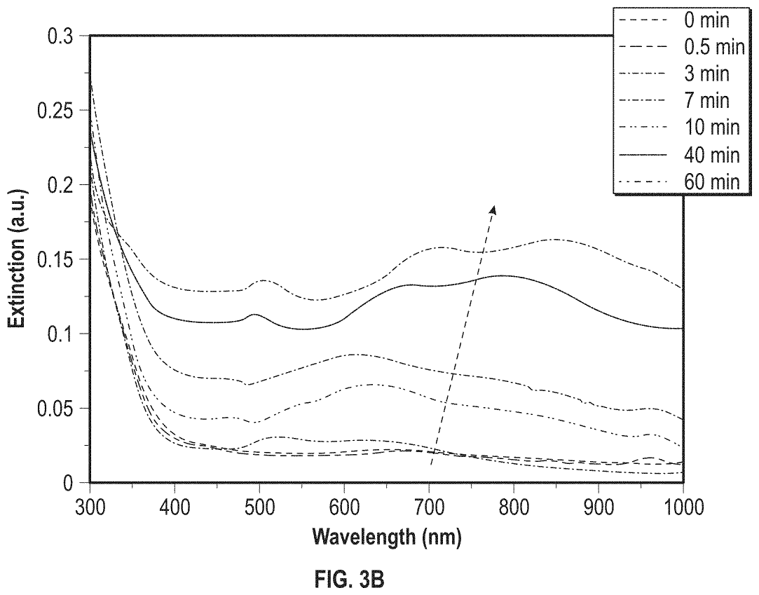

A 5.8 g sample of Cu₂O nanocube (NC) material was synthesized via wet reduction method with the reducing agent being sodium ascorbate. The diameter size of the NC particle was found via TEM microscopy technique and was measured to be an average of 300 nm for the adopted procedure used in this study. The smaller spherical 5.8 g of Cu₂O nanoparticle (NP) was synthesized via microemulsion method (reducing agent being Hydrazine 0.01M solution) and was measured similarly to be an average of 70-100 nm in diameter. In contrast, the larger spherical 5.8 g of Cu₂O NP was synthesized via wet reduction method (reducing agent Hydrazine Hydrate solution) and was measured to be an average of 300 nm in diameter. The particles were washed with acetone (3 times for NC, 4 times for NP) via centrifugation and redispersed in the necessary solvent needed for the individual experiments. FIG. 3A shows the differences between Cu₂O NP and NC, including UV Spectra and TEM images. FIG. 3B shows the change in NC UV-VIS spectra across synthetization time.

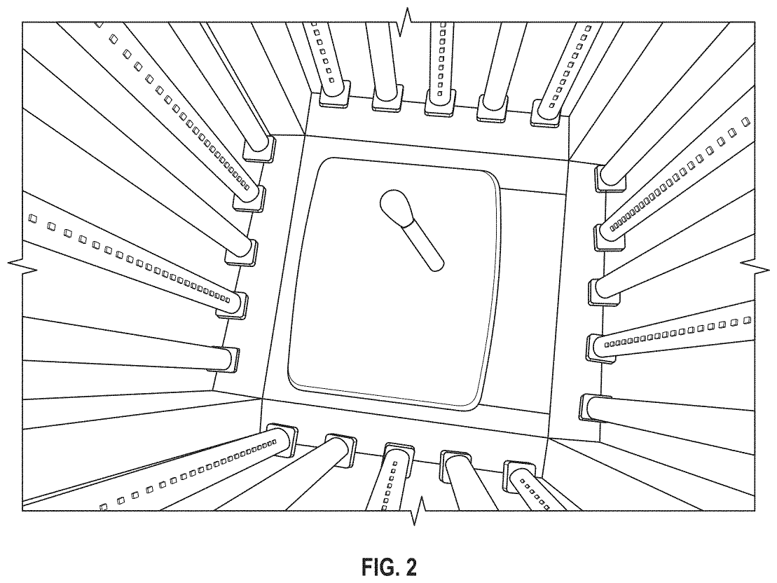

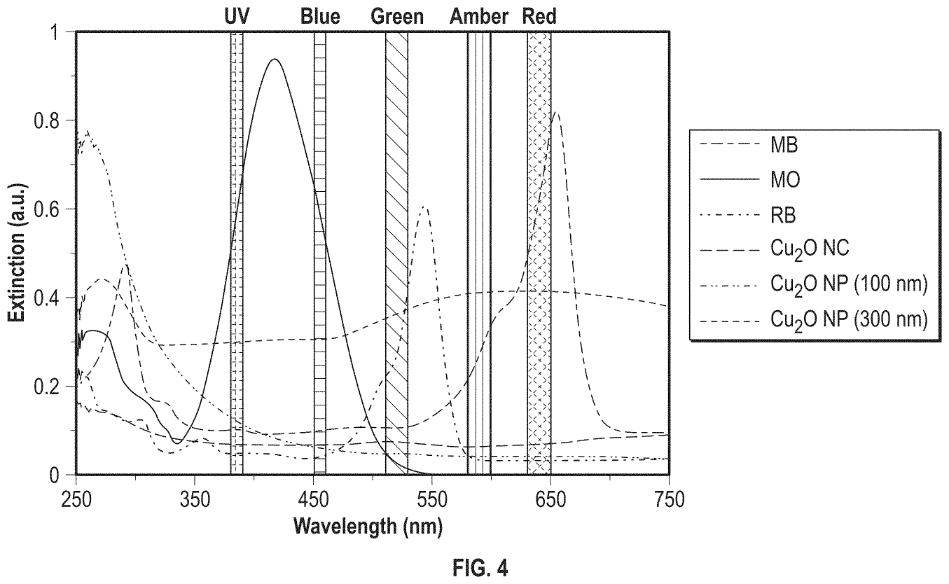

This study utilized various dyes as reactant probes to test for the degradation capabilities of the Cu₂O novel material under various conditions. The dyes used were TCI Chemical Methylene Blue Hydrate (>70.0%), Acros Organics Methyl Orange, and SIGMA Rhodamine B. A Luzchem EXPO-01 photoreactor, as shown in FIG. 2, was also utilized in this study with the LZC-LUV ultraviolet LED lamp, LZC-LBL blue LED lamp, LZC-LGR green LED lamp, LZC-LAM amber LED lamp, and the LZC-LRD red LED lamp for specific light wavelength experiments. A 6 mL quartz tube was used as the reactor chamber for this study due to the fact that the quartz material does not absorb light in the visible light range. The Methylene Blue (MB) dye was diluted with 200 Proof EtOH to make a 0.01M solution; 1004 of this solution was then suspended in 4 mL of EtOH to make the initial reactant solution. The Methyl Orange (MO) dye was diluted with deionized water to make a 0.01M solution; 1004 of this solution was then suspended in 4 mL of deionized water to make the initial reactant solution. FIG. 4 displays these various dyes and the accompanying catalysts used in this study in addition to the wavelength ranges of the Luzchem bulbs previously mentioned. A 6 mL quartz flask containing the 4 mL of reactant solution was then hoisted from string and allowed to sit and stir at the base of the Luzchem EXP-01 photoreactor. The Luzchem photoreactor was stored in a laboratory fume hood designed to eliminate any outside light from interacting with the reactor chamber. Furthermore, the Luzchem photoreactor can hold 20 bulbs, and depending upon which experiment was to be run, either a combination of 20 of the same bulbs or 2 different sets of 10 bulbs were plugged into the photoreactor for each experiment. Throughout the experimental process, an Agilent Technologies Cary 60 UV-Vis spectrophotometer was used to measure the degradation of the 1004 samples taken from the reactant solution over time. All experiments were run isothermally at a room temperature of 24° C.

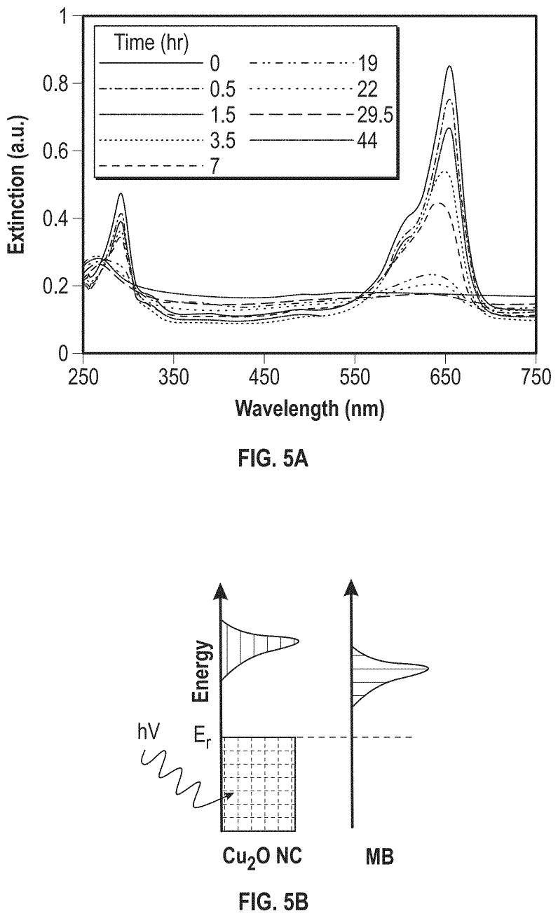

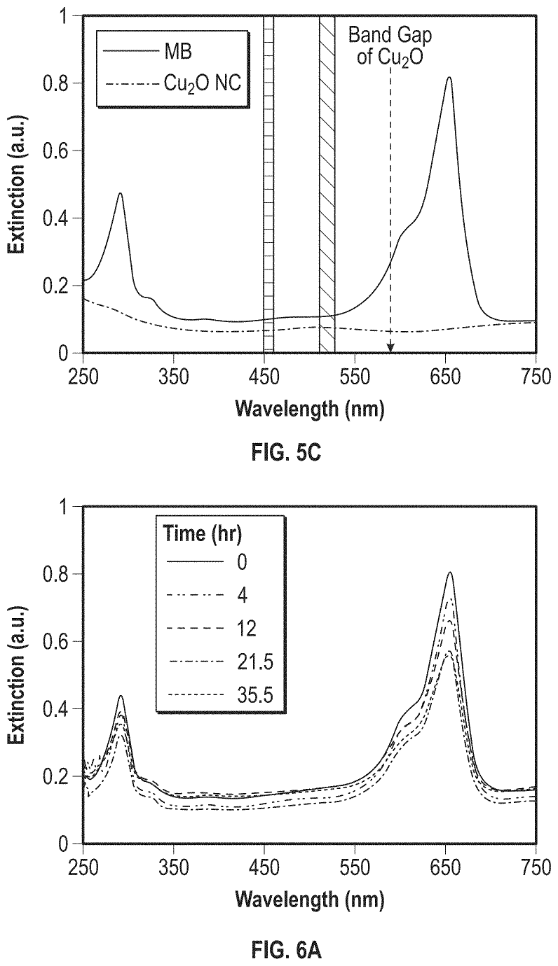

FIG. 5A shows the evolution of the MB dye over a period of 44 hours, with the dye being 79% degraded over that time period. This experiment was replicated for accuracy with near identical results as can be seen in the supporting information. In this particular experiment, the Luzchem bulbs used were capable of generating enough energy needed to exceed the bandgap and degradation occurred as expected. Due to the lack of overlap between the MB dye's peak absorbance (˜655 nm) and the bulbs used, the Near Field Effect mechanism was deemed highly improbable in this case.

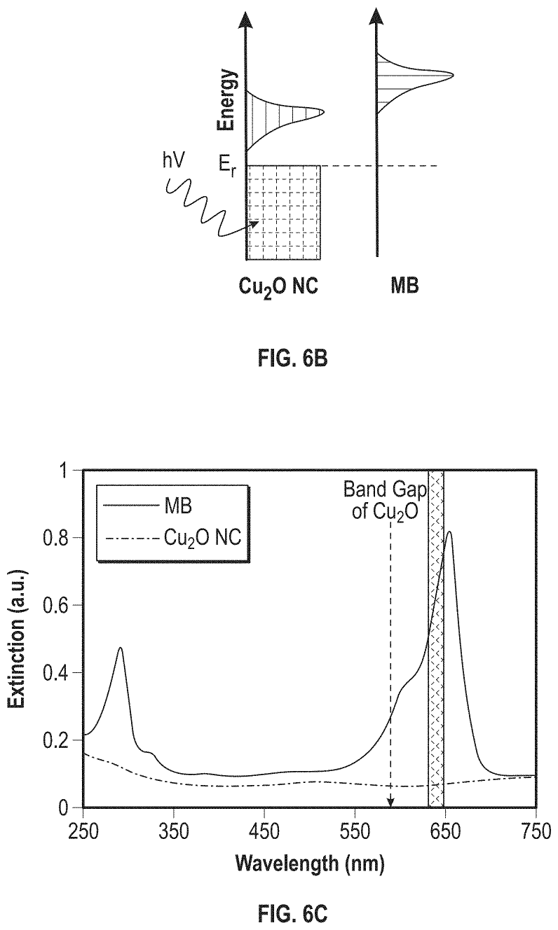

FIG. 6A shows the evolution of the MB dye over a period of 35.5 hours, with the dye being 31% degraded over that time period, a rate significantly slower than with the LZC-LBL & LZC-LGR bulbs. In this experiment, the LZC-LRD bulbs did not generate enough energy to exceed the bandgap, making the possibility of a plasmonic bandgap mediated electron transfer mechanism highly improbable. However, there is slight overlap between the MB peak absorbance and LZC-LRD bulbs absorbance, opening up the possibility of MRET mediated NFE in addition to MRET energy transfer. In order to determine if MRET energy transfer was possible or occurring in the absence of any Near Field effects, the Dye was switched Methyl Orange, which has a peak absorbance of ˜464 nm.

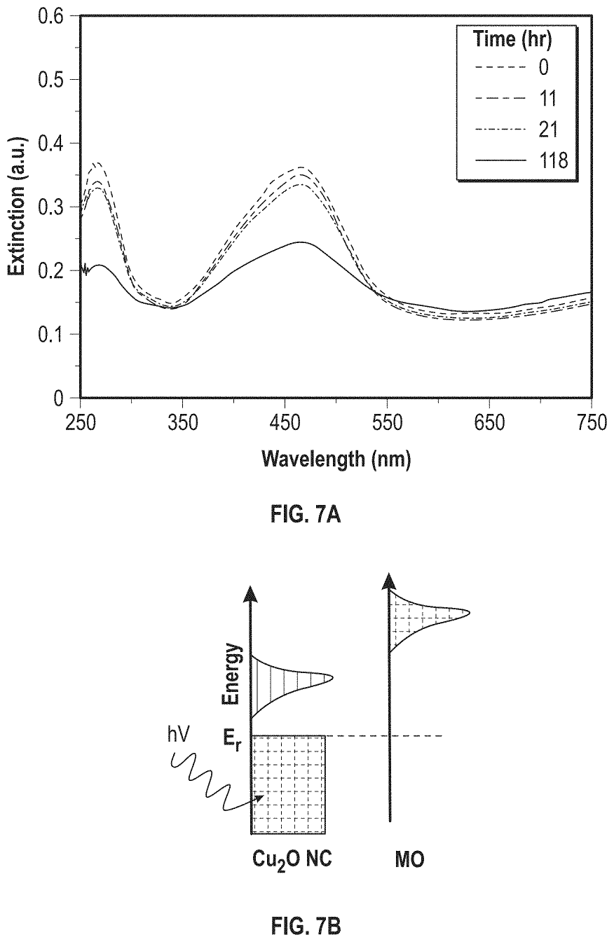

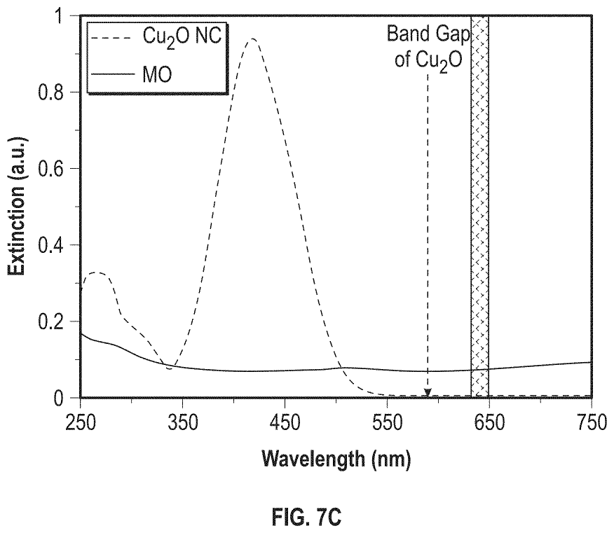

FIG. 7A shows the evolution of the MO dye over a period of 118 hours, with the dye being 33% degraded over that time period, a rate significantly slower than both previous experiments performed using the MB dye. Just as the previous experiment, the LZC-LRD bulbs did not generate enough energy to exceed the bandgap, making the possibility of a plasmonic bandgap mediated electron transfer mechanism highly improbable. The MO dye peak absorbance also suggested that any Near Field Effects were highly improbable in this case, leading to conclusion that MRET energy transfer was the only possible mechanism in this case.

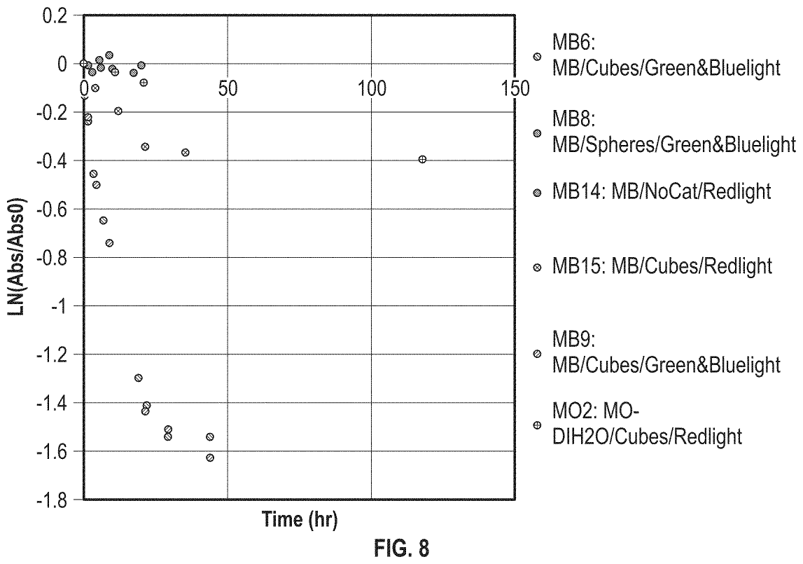

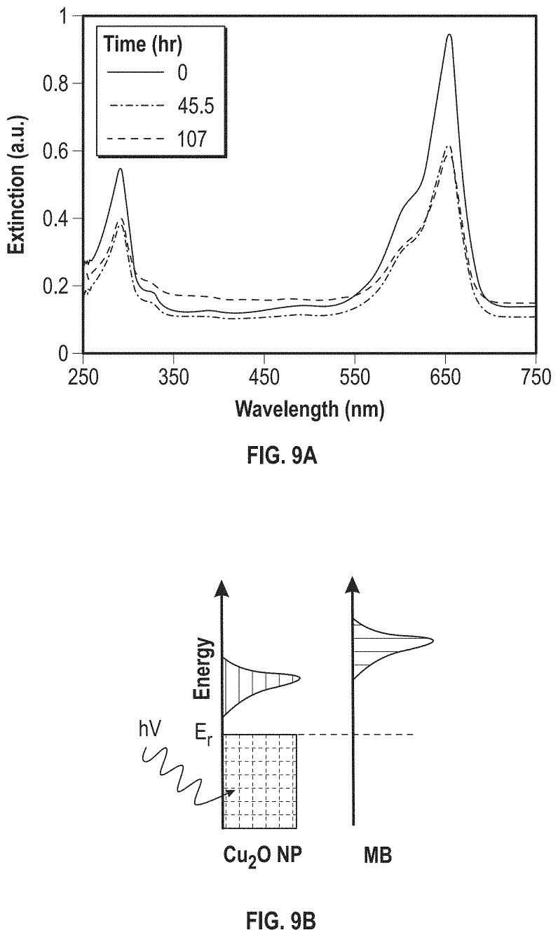

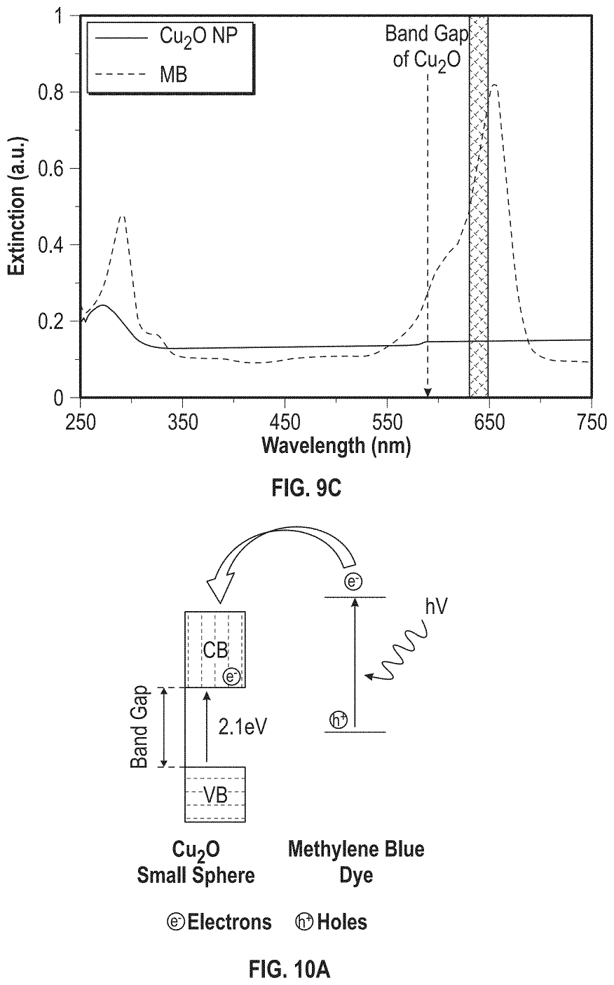

FIG. 8 shows results of the experimentation involving the use of the NC Cu₂O material in successful energy transfer (degradation). The images in FIGS. 9A, 9B and 9C detail how degradation is not only limited to Cu₂O nanocubes, but is possible with Cu₂O nanospheres as well. In comparison with the same experiment ran with the nanocubes, the MB degraded at a similar rate when the nanospheres were utilized. This experiment was allowed to run for a longer period of time and interestingly, it appears the degradation rate slows down exponentially after around 30% conversion is reached.

In summary, the results in this Example 1 show that the novel material Cu₂O provides an additional energy transfer pathway between an optical illumination source and a targeted adsorbate molecule. Thus, energy transfers that occur between the Cu₂O material and the target adsorbate happen via Mie Resonance mediated Energy and Electron Transfer (MRET), which possesses the unique trait of having the capacity to occur below the conduction band.

### EXAMPLE 2

To understand the underlying mechanisms of the MRET concept, experiments were designed to determine dye degradation mechanisms (adsorbate). We are reporting here for the first time that sub-micron size larger semiconductor particles (e.g., Cu₂O cubes) can enhance dye sensitization of methylene blue dye. Also, for the first time, photocatalytic degradation of methylene blue dye under illumination of red light and underlying sensitization mechanism was found to be Mie resonance mediated dye sensitization. Dye degradation experiments were performed with Cu₂O nanocubes (NCs) and Cu₂O small spheres (NPs) and found that larger size of nanoparticles cause effective degradation.

In this work we used various experimental methods and characterization techniques like UV-Vis spectroscopy, TEM and XRD to identify and track organic dye degradation over time via the observable degradation of the organic dye absorption, shape and size of the nanoparticles and surface facets respectively. Computational methods (FDTD) with various semi-conductor materials like Cu₂O, Fe₂O₃, TiO₂ large nanocubes for various sizes ranging from 400-50 nm and show a similar trend. These catalysts find applications in harvesting solar energy, thin film solar cells, dye sensitized solar cells and chemical related industries.

Mie nanostructures or Mie particles exhibit exciting properties of their electric and magnetic fields such as for various particle shapes like spheres or cubes exhibit magnetic dipole resonances, which instigate from the excitation of circular displacement currents in the particle. In these structures the fields can fully penetrate the particles and field maxima are typically found inside of the nanoparticles as compared to fields limited to the surface of the nanostructure in plasmonics. Abundantly available dielectric Cu₂O nanostructures could be a viable alternative to be utilized in Mie resonance-based dye sensitized solar cells (DNSCs) and thin film solar cells. In this work we are utilizing Mie resonance enhanced dye sensitization mechanism as a proof for electron harvesting ability of Cu₂O nanostructures and also show evidences for the mechanism.

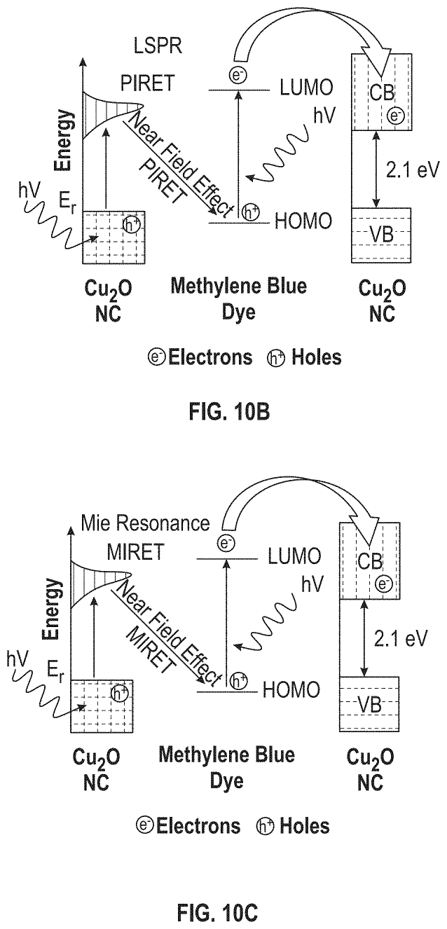

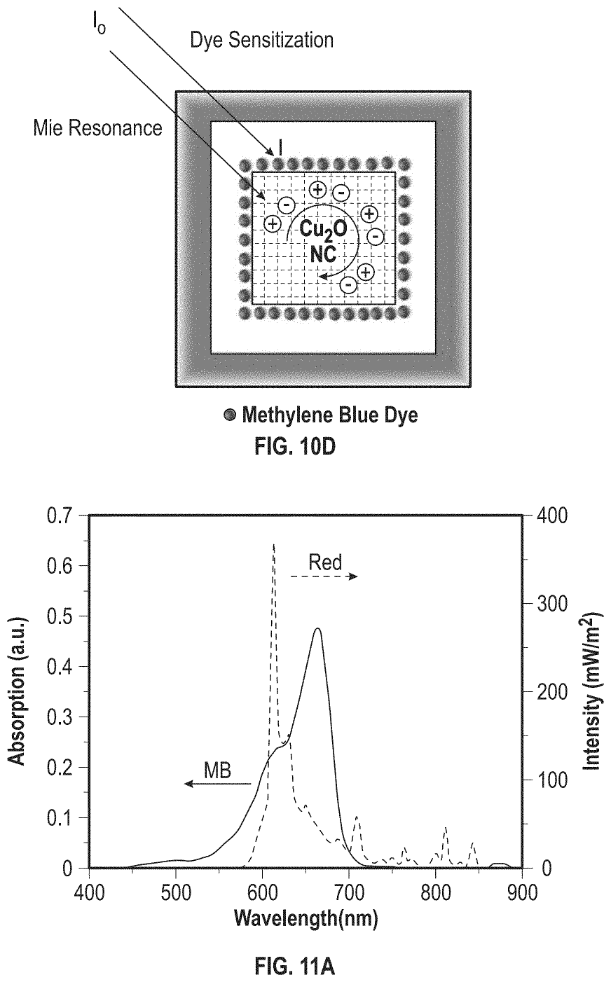

FIG. 10A-10D shows various photon driven dye sensitization mechanisms discussed using the semiconductor, plasmonic and dielectric particles. Referring to FIG. 10A, as light is incident on the dye the electrons acquire the energy from photons and charge transfers to the conduction band of the semiconductor material in the process, sensitizing the dye leading to further photocatalysis and electron harvesting. Dye gets sensitized on a plasmonic nanoparticle (PMNs) through PIRET-mediated electron transfer and near field effect exciting electrons in the lowest unoccupied molecular orbital (LUMO) to the highest occupied molecular orbital (HOMO) destabilizing the dye, these electrons can be harvested using the semiconductor for energy generation as shown in FIG. 10B and could be used for a wide range of Plasmonic metal nanostructures (PMNs) and semiconductor (SCs). Based on these dye sensitization mechanisms from literature, we endorse Mie-resonance mediated dye sensitization mechanism. As light is incident on dielectric material such as Cu₂O nanocubes the excited electrons can excite more electrons from LUMO to HOMO to sensitize the dye through Mie-induced resonance energy transfer (MIRET), near field effect. This helps in harvesting more electrons on these Mie particles potentially used in solar energy applications.

Materials and Methods

UV-Visible spectroscopy: UV-Vis spectra were obtained using an Agilent Cary 60 Spectrophotometer to monitor the dye sensitization through degradation of methylene blue in the reaction mixture under illumination of red light. For the UV-Vis extinction spectra measurements of the reaction mixture, an aliquot of 100 μL was taken from the reaction mixture and diluted into 4 mL of solvent used in the reaction and sonicated for a minute for good homogenization of the mixture which was then used for UV-Vis spectroscopic measurements.

Transition electron microscopy (TEM): For TEM imaging, an aliquot of 150 μL of the washed catalyst was diluted in 2 mL of ethanol. The sample was sonicated for 1 min to break up any agglomeration of nanoparticles in solution. 10 μL of this sample was then taken and put onto the supported TEM grid as a single droplet. The sample could dry in air for approximately 5-10 minutes. The TEM measurements were performed on a JEOL-2100. The accelerating voltage was 200 kV with a LaB6 gun.

Photocatalytic dye sensitization reaction conditions: Cu₂O NCs and NPs were synthesized by the chemical reduction method and microemulsion method respectively. They were suspended in solvent (4 mL) prior to starting the reaction (5.8 mg) in a quartz test tube. This mixture was added with methylene blue dye (150 uL) and allowed to equilibrate for 3 hours to make sure the mixture attains adsorption equilibrium. The test tube was safely moved to the Luz Chem illumination system (setup shown in SI), where 20 red light LED lamps with wavelength ranging from 590-630 nm were arranged, each bulb has power output of 8 Watt. The corresponding intensities of blue and green light are mentioned in FIG. 2A here can observe that the light intensities significantly overlap with the absorption spectra of methylene blue.

Photocatalytic dye sensitization reaction using benzoquinone conditions: The catalysts synthesized (5.8 mg) were suspended in de-oxygenated solvent (4 mL) prior to starting the reaction in a quartz test tube. This mixture was added with 43.2 mg of benzoquinone which is a O₂− radical scavenger and doped with methylene blue dye (150 uL) and allowed to equilibrate for 3 hours to make sure the mixture attains adsorption equilibrium. For tracking the degradation using UV-visible spectroscopy an aliquot of 100 μL of the reaction mixture was diluted in 4 mL of the same solvent used in the reaction in inert atmosphere. The sample was sonicated for 1 min to homogenize the solution and the absorption spectra was obtained. The methylene blue degradation was tracked using the primary maxima absorption value to concentration fraction (C/C₀) calculated based on the equation shown below:

$$Concentration ( X , \% ) = \frac{C}{{C}_{0}}$$

where C₀ is the concentration of methylene blue measured after equilibration.

Microemulsion method for Cu₂O spheres: The Cu₂O nano spheres (NPs) were prepared using the reverse microemulsion method. In this method, n-heptane, polyethylene glycol-dodecyl ether (Brij, average Mn ^{˜}362 as surfactant), copper nitrate as precursor, and hydrazine as reducing agent were used. These chemicals were added in the following sequence and quantity. First, 54.5 mL of n-heptane was added to three-neck round bottom flask at room temperature, followed by 7.5 mL of Brij surfactant addition and stirred for uniformity. Then 5.4 mL of 0.1 M copper nitrate aqueous solution was added, followed by 5.4 mL of 1 M of aqueous hydrazine solution. After 12 hours of the synthesis the mixture was washed using acetone to break the emulsion leading to precipitation of the Cu₂O NPs. These nanoparticles were further washed to obtain surfactant free nanoparticles. From which an aliquot of 150 uL in 2 mL ethanol was taken and further 600 uL from this aliquot was diluted in 3 mL of ethanol. This synthesis provides 32 mg of Cu₂O NPs which is suspended in the required solvent of interest and 5.8 mg of Cu₂O NPs were used in the reaction.

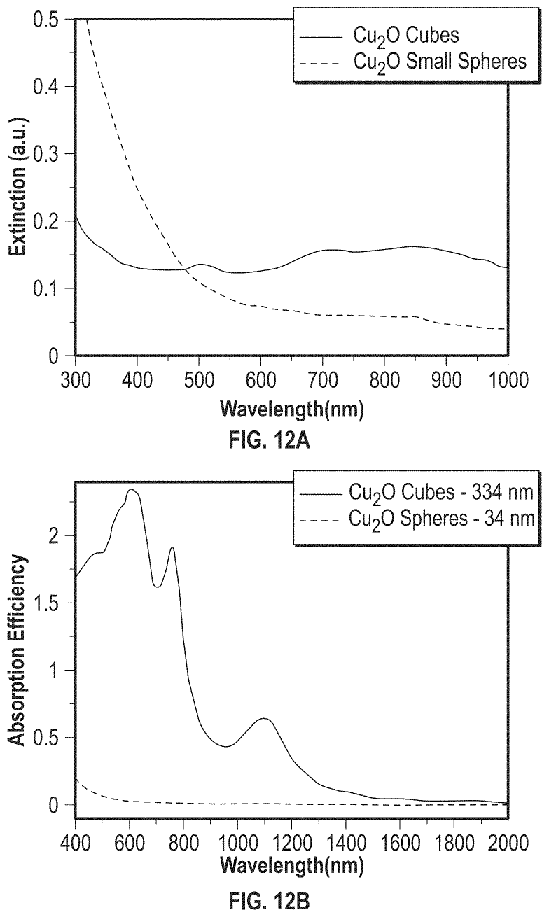

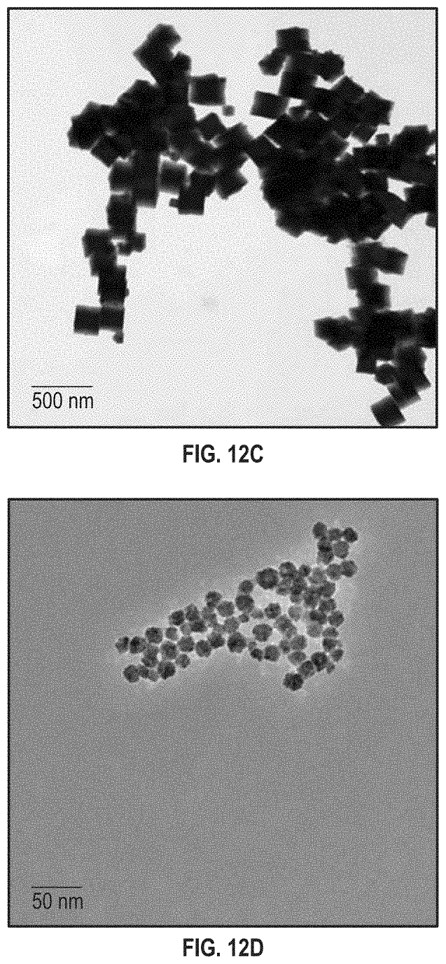

Chemical reduction method for Cu₂O cubes: The chemical reduction method reported in the literature was used for the synthesis of Cu₂O cubes. Using this method, 12.8 mg of anhydrous CuCl₂ to 30 mL DI water in a three-neck round bottom flask, which is blanketed continuously by flowing nitrogen for inertion. Addition of 1 mL of 0.35 M aqueous NaOH solution turns the solution blue in color as a result of Cu (OH)₂ colloids formation immediately. Consequently, 1 mL of sodium ascorbate (reducing agent) was added. The solution then became from solecent green to bright orange in the course of an hour, indicating the formation of Cu₂O nanocubes (NCs). The synthesis was done at room temperature and nitrogen environment. An aliquot of 100 uL in 2 mL of DI water was used for acquiring the extinction spectra as shown in FIG. 12A. These nanocubes were washed using ethanol. This synthesis provides 12.8 mg of Cu₂O NCs which are suspended in the required solvent of interest and 5.8 mg of Cu₂O NCs were used in the reaction.

As shown in FIG. 12B, attached to the surface of the Cu₂O nanostructure is a layer of the charge transfer dye. Photo excitation of the dye results in sensitization consequently injection of an electron into the conduction band of the copper oxide. The original state of the dye is subsequently restored by electron donation from the dissolved oxygen in the organic solvent.

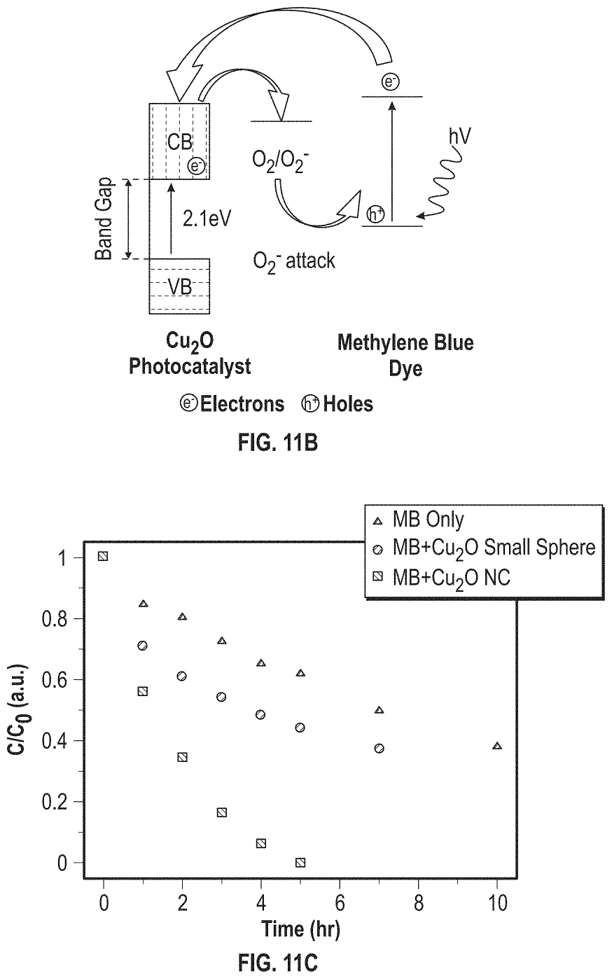

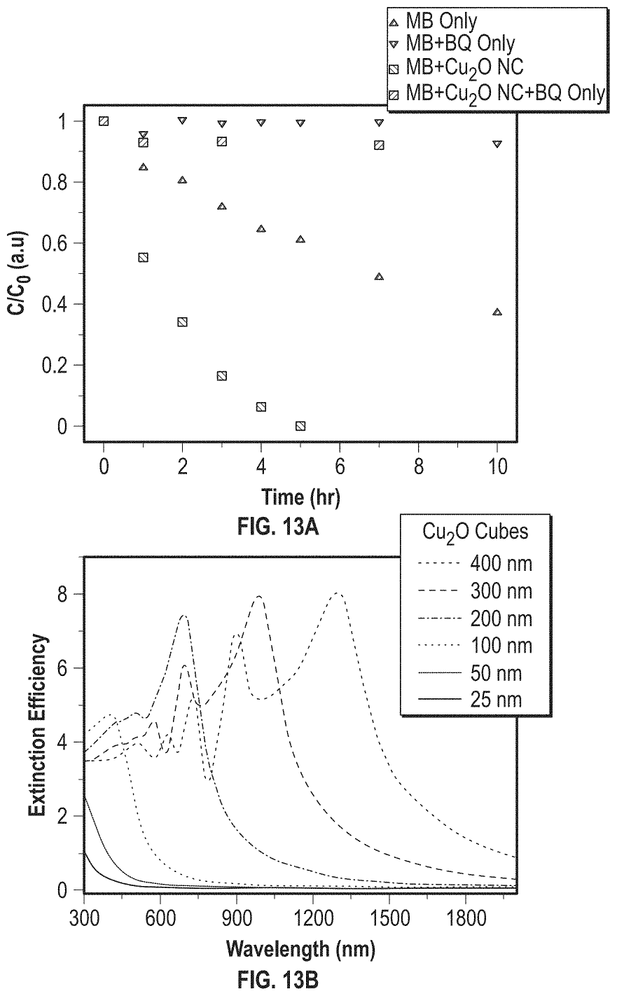

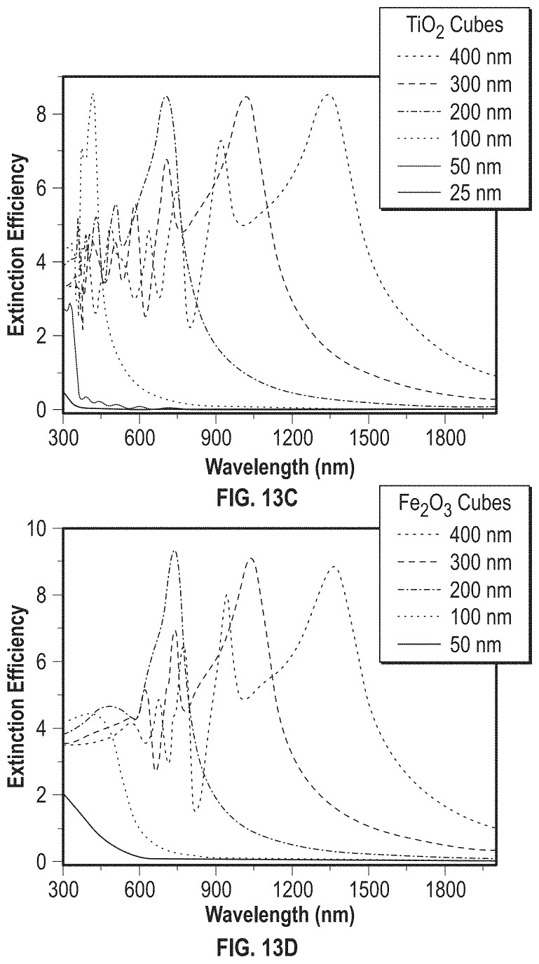

Referring back to FIG. 11A, there is significant overlap of absorption spectra of methylene blue to the red light illumination used in the reaction showing as light is incident on the dye molecules, excited electrons are excited to HOMO level which can be transferred to the conduction band of the photocatalyst (here Cu₂O NPs), sensitizing the dye. The harvested electrons generate O₂⁻ radicals consequently reducing the already sensitized due molecule easily to degraded products as shown in FIG. 11B. Experimental evidences show that Cu₂O NCs has significant faster degradation of the dye in comparison to spheres and absence of catalyst due to the Mie-induced resonance energy transfer (MIRET) and Near field effect enhanced photocatalysis as observed in FIG. 11C. Cu₂O NPs which are small spheres (See FIG. 13D) show slightly effective degradation to the absence of catalyst under illumination of red light in DMF, due to the semiconductor properties of Cu₂O where dye sensitization allows excited electrons to transfer to conduction band of Cu₂O NPs as suggested in FIG. 10B which could lead to degradation of the dye.

Absorption Spectra of Cu₂O NCs (Cubes) and Cu₂O NPs (Small Spheres) synthesized using De-wetting technique and micro-emulsion methods are shown in FIG. 12A where UV-Vis-near IR extinction measurements indicate they are small particles with 2.1 eV and Cu₂O nanocubes (NCs) show a sign of Mie resonance peaks around 850 and 700 nm as primary and secondary peaks respectively which is used for degradation of methylene blue. Cu₂O NCs (Cubes) and Cu₂O NPs (Small Spheres) of size 327±125 nm and 47±6 nm respectively was measured through TEM analysis as shown in FIG. 12C and FIG. 12D, based on which finite difference time domain (FDTD) simulations of size 334 and 34 nm were performed. As shown in FIG. 12B computed absorption efficiency for cubes and spheres show that higher absorption efficiency was observed in large cubes showing the ability of the large Cu₂O cubes to generate strong Mie resonance.

Significant photocatalytic degradation of methylene blue was observed (see FIG. 13A) under radiance of red lamps using the Cu₂O NCs using the same experimental configuration discussed in methods section in DMF where the reaction was exposed to air atmosphere. We predicted that Mie-resonance mediated dye sensitization mechanism which consumes O₂− radical with oxygen sourced by dissolved free oxygen in the solvent without which the reaction could not proceed (see FIG. 11B). To verify this hypothesis, we used benzoquinone which scavenges O₂− radical not allowing the reaction mechanism to complete. As observed in FIG. 13B we can confirm that with and without benzoquinone the reaction does not proceed in the presence of benzoquinone which verifies the hypothesis. As described in FIG. 13A as red light is illuminated on Cu₂O NCs, through Mie resonance electron transfer (MIRET) and near field effect, O₂− radical is formed by acquiring the excited electron from the conduction band which leads to reducing methylene blue to degraded products irreversibly. To evidently observe it methylene blue was subjected to illumination of red light with benzoquinone under inert atmospheric conditions we can observe no degradation reinforcing the suggested hypothesis. No degradation of methylene blue is observed in blank solvent and with benzoquinone in the absence of catalyst as shown in FIG. 13A. FDTD simulations for materials with high and medium refractive index like TiO₂ and Fe₂O₃ respectively, computed absorption spectra for various sizes of nanocubes ranging from 25 to 300 nm are shown in FIG. 13C and FIG. 13D infers that tuning the size of the nanocubes we can tune the absorption efficiency in UV-Visible and near IR region of the electromagnetic spectra to show higher rate of photocatalysis or higher electron harvesting ability to be used in Dye sensitized solar cells. This observation can be also be applied to Cu₂O nanocubes as shown in FIG. 13B.

### Discussion of Results

For the first time we have shown the photocatalytic ability of Mie resonances in photocatalysis by sensitizing methylene blue using Cu₂O nanocubes. In FIG. 11A we observe that methylene blue shows significant overlap to the illuminated wavelengths of red light which infers that methylene blue dye can absorb red light efficiently potentially sensitizing the dye. It is evident from FIG. 11C that the large cubes lead to higher degradation of methylene blue under illumination in comparison to Cu₂O small spheres citing the ability of the cubes to generate strong Mie resonances under illumination. Cu₂O small spheres show slightly higher degradation than in blank solvent attributing it to the transferred electrons to this photocatalyst due to dye sensitization and further generating O₂− radicals consequently reducing the dye as shown in FIG. 11B. Under deprivation of oxygen, benzoquinone is used to scavenge O₂− radical, not allowing the degradation to occur which was verified experimentally in FIG. 13A citing that using Cu₂O nanocubes Mie resonance mediated electron transfer (MIRET) and Near field effect responsible for exciting electrons to the lowest unoccupied molecular orbital (LUMO) energy level of the dye to further sensitize it, to degrade methylene blue dye in the presence of oxygen to degraded products irreversibly reinforcing the mechanism proposed. The ability to tune the absorption efficiency across the UV-visible and Near IR region by tuning the size of the particles marks its flexibility in various energy applications and photocatalysis. This photocatalytic system can be envisioned as a method to harvest more electrons for generating photon energy using dye sensitized solar cells (DNSCs) potentially reducing the thickness and cost of the (DNSCs) and increasing the ability to harvest electrons consequently the higher energy density.

### Photocatalytic Reactor Design

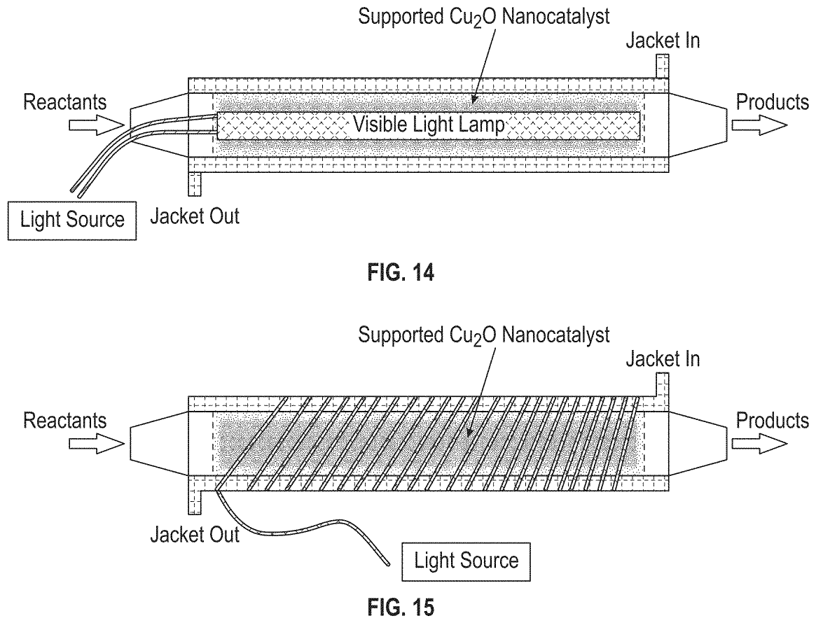

Two general reactor designs are considered for using a photocatalytic flow reactor with supported nanocatalyst, for example Cu₂O supported on SiO₂. In FIG. 14, light illumination is from inside of the annular flow reactor. In FIG. 15, light illumination is from outside of the flow reactor.

### Non-Limiting Illustrative Embodiments of the Inventive Concept(s)

The following is a numbered list of non-limiting illustrative embodiments.

1. A photocatalytic composition, comprising:
dielectric particles in combination with a reactant, the dielectric particles sized and shaped to produce electron excitations and subsequent user-defined chemical transformation of the reactant without exceeding a band gap energy barrier of the dielectric particles.

2. The photocatalytic composition of illustrative embodiment 1, wherein the dielectric particles have a weight-average particle diameter in a range of from about 75 nm to about 400 nm.

3. The photocatalytic composition of any one of illustrative embodiments 1 or 2, wherein the dielectric particles are formed in a shape selected from spheres, cubes, rectangular bars, octahedrons, cubo-octahedrons, and triangular plates.

4. The photocatalytic composition of illustrative embodiment 1, wherein the dielectric particles are generally spherical in shape.

5. The photocatalytic composition of illustrative embodiment 4, wherein the dielectric particles have a weight-average particle diameter in a range of from about 40 nm to about 60 nm.

6. The photocatalytic composition of illustrative embodiment 1, wherein the dielectric particles are generally cubic in shape.

7. The photocatalytic composition of illustrative embodiment 6, wherein the dielectric particles have a weight-average particle diameter in a range of from about 250 nm to about 400 nm.

8. The photocatalytic composition of illustrative embodiment 1, wherein the dielectric particles comprise a chemical composition selected from Cu₂O, Fe₂O₃, and TiO₂.

9. The photocatalytic composition of illustrative embodiment 1, wherein the dielectric particles comprise Cu₂O.

10. The photocatalytic composition of illustrative embodiment 9, wherein the dielectric particles are generally cubic in shape.

11. The photocatalytic composition of illustrative embodiment 10, wherein the dielectric particles have a weight-average particle diameter in a range of from about 250 nm to about 400 nm.

12. The photocatalytic composition of illustrative embodiment 9, wherein the dielectric particles are generally spherical in shape.

13. The photocatalytic composition of illustrative embodiment 12, wherein the dielectric particles have a weight-average particle diameter in a range of from about 40 nm to about 60 nm.

14. The photocatalytic composition of any one of illustrative embodiments 1-7, wherein the dielectric particles comprise TiO₂.

15. The photocatalytic composition of any one of illustrative embodiments 1-7, wherein the dielectric particles comprise Fe₂O₃.

16. The photocatalytic composition of any one of illustrative embodiments 1-15, wherein the reactant is at least partially adsorbed onto surfaces of the dielectric particles.

17. A treatment method comprising the step of:

irradiating a reactant and the photocatalytic composition of illustrative embodiment 1 with light having a lower energy than a band gap energy of said photocatalytic composition so as to cause a chemical reaction in the reactant.

18. The method of illustrative embodiment 17, wherein the irradiating light has a wavelength longer than ultraviolet.

19. The method of illustrative embodiment 17, wherein the irradiating light is in the visible spectrum.

20. The method of any one of illustrative embodiments 17 to 19, wherein the irradiating light comprises at least one of solar light and artificial light.

21. A photocatalysis system having an illumination source, an adsorbate, and dielectric particles in contact with the adsorbate, the dielectric particles sized and shaped to produce electron excitations and subsequent chemical transformation of the reactant without exceeding a band gap energy barrier of the dielectric particles.

22. The photocatalysis system of illustrative embodiment 21, wherein the adsorbate comprises a dye with a color and color wavelength within the visible light spectrum, and wherein the illumination source comprises light having a wavelength longer than the dye color wavelength.

23. A solar cell comprising:
a working electrode comprising dielectric particles with a photosensitive dye absorbed thereon, the dielectric particles sized and shaped to produce electron excitations without exceeding a band gap energy barrier of the dielectric particles;
electrolyte; and
a counter electrode.

24. A solar cell comprising:
a working electrode comprising dielectric particles with a photosensitive dye absorbed thereon, the dielectric particles sized and shaped to produce Mie resonance mediated electron transfer upon irradiation for exciting electrons to the lowest unoccupied molecular orbital (LUMO) energy level of the photosensitive dye to further sensitize the photosensitive dye.

Thus, in accordance with the present disclosure, there have been provided compositions, as well as methods of producing and using same, which fully satisfy the objectives and advantages set forth hereinabove. Although the present disclosure has been described in conjunction with the specific drawings, experimentation, results, and language set forth hereinabove, it is evident that many alternatives, modifications, and variations will be apparent to those skilled in the art. Accordingly, it is intended to embrace all such alternatives, modifications, and variations that fall within the spirit and broad scope of the present disclosure.

What is claimed is:

1. A photocatalytic composition, comprising:
dielectric particles in combination with a reactant, the dielectric particles sized and shaped to produce electron excitations and subsequent user-defined chemical transformation of the reactant without exceeding a band gap energy barrier of the dielectric particles.

2. The photocatalytic composition of claim 1, wherein the dielectric particles have a weight-average particle diameter in a range of from about 75 nm to about 400 nm.

3. The photocatalytic composition of any one of claim 1 or 2, wherein the dielectric particles are formed in a shape selected from spheres, cubes, rectangular bars, octahedrons, cubo-octahedrons, and triangular plates.

4. The photocatalytic composition of claim 1, wherein the dielectric particles are generally spherical in shape.

5. The photocatalytic composition of claim 4, wherein the dielectric particles have a weight-average particle diameter in a range of from about 40 nm to about 60 nm.

6. The photocatalytic composition of claim 1, wherein the dielectric particles are generally cubic in shape.

7. The photocatalytic composition of claim 6, wherein the dielectric particles have a weight-average particle diameter in a range of from about 250 nm to about 400 nm.

8. The photocatalytic composition of claim 1, wherein the dielectric particles comprise a chemical composition selected from Cu₂O, Fe₂O₃, and TiO₂.

9. The photocatalytic composition of claim 1, wherein the dielectric particles comprise Cu₂O.

10. The photocatalytic composition of claim 9, wherein the dielectric particles are generally cubic in shape.

11. The photocatalytic composition of claim 10, wherein the dielectric particles have a weight-average particle diameter in a range of from about 250 nm to about 400 nm.

12. The photocatalytic composition of claim 9, wherein the dielectric particles are generally spherical in shape.

13. The photocatalytic composition of claim 12, wherein the dielectric particles have a weight-average particle diameter in a range of from about 40 nm to about 60 nm.

14. The photocatalytic composition of any one of claims 1-7, wherein the dielectric particles comprise TiO₂.

15. The photocatalytic composition of any one of claims 1-7, wherein the dielectric particles comprise Fe₂O₃.

16. The photocatalytic composition of any one of claims 1-15, wherein the reactant is at least partially adsorbed onto surfaces of the dielectric particles.

17. A treatment method comprising the step of:
irradiating a reactant and the photocatalytic composition of claim 1 with light having a lower energy than a band gap energy of said photocatalytic composition so as to cause a chemical reaction in the reactant.

18. The method of claim 17, wherein the irradiating light has a wavelength longer than ultraviolet.

19. The method of claim 17, wherein the irradiating light is in the visible spectrum.

20. The method of any one of claims 17 to 19, wherein the irradiating light comprises at least one of solar light and artificial light.

21. A photocatalysis system having an illumination source, an adsorbate, and dielectric particles in contact with the adsorbate, the dielectric particles sized and shaped to produce electron excitations and subsequent chemical transformation of the reactant without exceeding a band gap energy barrier of the dielectric particles.

22. The photocatalysis system of claim 21, wherein the adsorbate comprises a dye with a color and color wavelength within the visible light spectrum, and wherein the illumination source comprises light having a wavelength longer than the dye color wavelength.

23. A solar cell comprising:
a working electrode comprising dielectric particles with a photosensitive dye absorbed thereon, the dielectric particles sized and shaped to produce electron excitations without exceeding a band gap energy barrier of the dielectric particles;
electrolyte; and
a counter electrode.

24. A solar cell comprising:
a working electrode comprising dielectric particles with a photosensitive dye absorbed thereon, the dielectric particles sized and shaped to produce Mie resonance mediated electron transfer upon irradiation for exciting electrons to the lowest unoccupied molecular orbital (LUMO) energy level of the photosensitive dye to further sensitize the photosensitive dye.
